(19) United States
(12) Patent Application Publication
(10) Pub. No.: US 2026/0113888 A1
(43) Pub. Date: Apr. 23, 2026

(54) COOLING DEVICE

(71) Applicant: NIDEC CORPORATION, Kyoto (JP)

(72) Inventors: Kazuhiko FUKUSHIMA, Kyoto (JP); Takehito TAMAOKA, Kyoto (JP); Koji HATANAKA, Kyoto (JP); Shinya KIZAWA, Kyoto (JP)

(21) Appl. No.: 19/360,025

(22) Filed: Oct. 16, 2025

(30) Foreign Application Priority Data
Oct. 18, 2024 (JP) 2024-182943

(51) Int. Cl. H05K 7/20

(52) U.S. Cl. CPC H05K 7/2039; H05K 7/20254

(57) ABSTRACT

A cooling device includes a cold plate, fins, a first flow path, and a second flow path. The cold plate is movable into thermal contact with a heat source. The fins are on one main surface of two main surfaces of the cold plate and are arranged at intervals in the first direction. The first flow path is on one side of the plurality of fins on the one main surface in a second direction intersecting a first direction, and communicates with an inlet of the refrigerant. The second flow path is on another side of the plurality of fins on the one main surface in the second direction, and communicates with an outlet of the refrigerant. At least portions of the plurality of the fins overlap the first flow path or the second flow path in a plan view.

### CROSS-REFERENCE TO RELATED APPLICATIONS

The present application claims priority under 35 U.S.C. § 119 to Japanese Patent Application No. 2024-182943, filed on Oct. 18, 2024, the entire contents of which are hereby incorporated herein by reference.

### 1. Field of the Invention

The present disclosure relates to cooling devices.

### 2. Background

Conventionally, as a method of cooling a heating element such as a central processing unit (CPU), a cooling method using a refrigerant-type cooling device is known. The refrigerant-type cooling device includes a flow path inside, and the refrigerant (for example, water) flowing through the flow path transfers heat of the heating element to the outside to cool the heating element.

Conventionally, there is known a cooling device having a cooling channel constituted by an inlet channel communicating with an inlet for a refrigerant and extending in a first direction, an outlet channel communicating with an outlet for the refrigerant and extending in the first direction, and a lateral channel communicating with the inlet channel and the outlet channel and extending in a second direction intersecting the first direction. The refrigerant flows through the cooling channel.

However, in the conventional cooling device, since the flow path cross-sectional area of the lateral channel is smaller than the flow path cross-sectional areas of the inlet channel and the outlet channel, the flow path resistance increases at the inlet and the outlet of the lateral channel. Therefore, the circulation efficiency of the refrigerant may decrease, and the cooling performance may decrease. Therefore, provision of a cooling device having excellent cooling performance is needed.

### SUMMARY

A cooling device according to an example embodiment of the present disclosure includes a cold plate, a plurality of fins, a first flow path, and a second flow path. The cold plate is movable into thermal contact with a heat source. The plurality of fins are arranged at intervals in a first direction on one main surface of two main surfaces of the cold plate. The first flow path is on one side of the plurality of fins on the one main surface in a second direction intersecting a first direction, and communicates with an inlet of the refrigerant. The second flow path is on another side of the plurality of fins on the one main surface in the second direction, and communicates with an outlet of the refrigerant. At least portions of the plurality of the fins overlap the first flow path or the second flow path in a plan view.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic perspective view of a cooling device according to a first example embodiment of the present disclosure.

FIG. 2 is a schematic perspective view of the cooling device according to the first example embodiment.

FIG. 3 is a schematic perspective view of a cold plate according to the first example embodiment.

FIG. 4 is a schematic perspective view of an intermediate plate according to the first example embodiment.

FIG. 5 is a schematic perspective view of the intermediate plate according to the first example embodiment.

FIG. 6 is a schematic plan view of the cooling device according to the first example embodiment.

FIG. 7 is a cross-sectional view taken along line IV-IV shown in FIG. 1.

FIG. 8 is a cross-sectional view taken along line V-V shown in FIG. 1.

FIG. 9 is a schematic cross-sectional view of a cooling device according to a second example embodiment of the present disclosure.

### DETAILED DESCRIPTION

Hereinafter, cooling devices according to example embodiments of the present disclosure will be described in detail with reference to the drawings. The example embodiments described herein do not limit the present disclosure. Each example embodiment can be appropriately combined within a range in which processing contents do not contradict each other. In the following example embodiments, the same elements or features are denoted by the same reference numerals, and redundant description will be omitted.

In each of the drawings to be referred to below, an orthogonal coordinate system in which an X axis direction, a Y axis direction, and a Z axis direction orthogonal to one another are defined and the Z axis direction is a vertically upward direction may be shown for easy understanding of the description.

In the following description, the X axis direction corresponds to a “first direction”, the Y axis direction corresponds to a “second direction”, and the Z axis direction corresponds to a “third direction”. For example, the X axis direction and the Y axis direction are horizontal directions. The Z axis direction is an up-down direction.

The following description assumes that each of the X axis direction, the Y axis direction, and the Z axis direction includes an error range (e.g., a range of about ±45°) allowable in the technical field to which the present disclosure belongs. As an example, “extending in the X axis direction” includes not only extending in the X axis direction in a strict sense, but also extending in a direction shifted by a range of about ±45° with respect to the X axis direction.

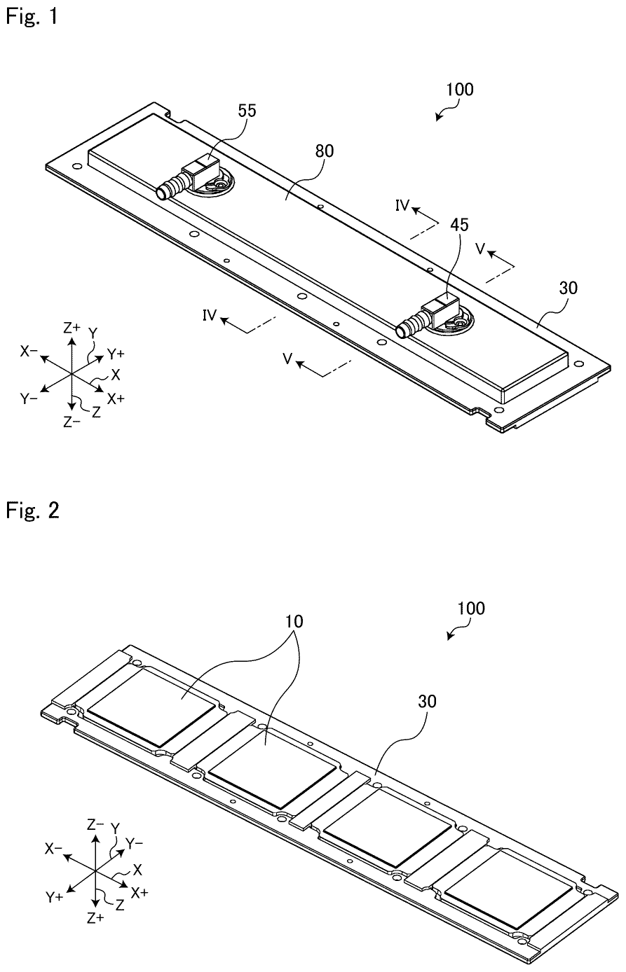

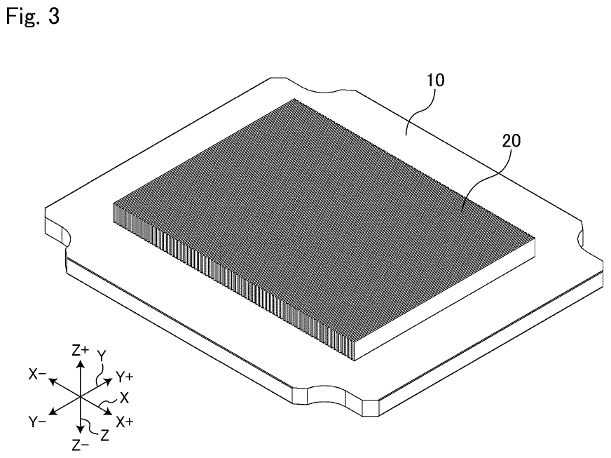

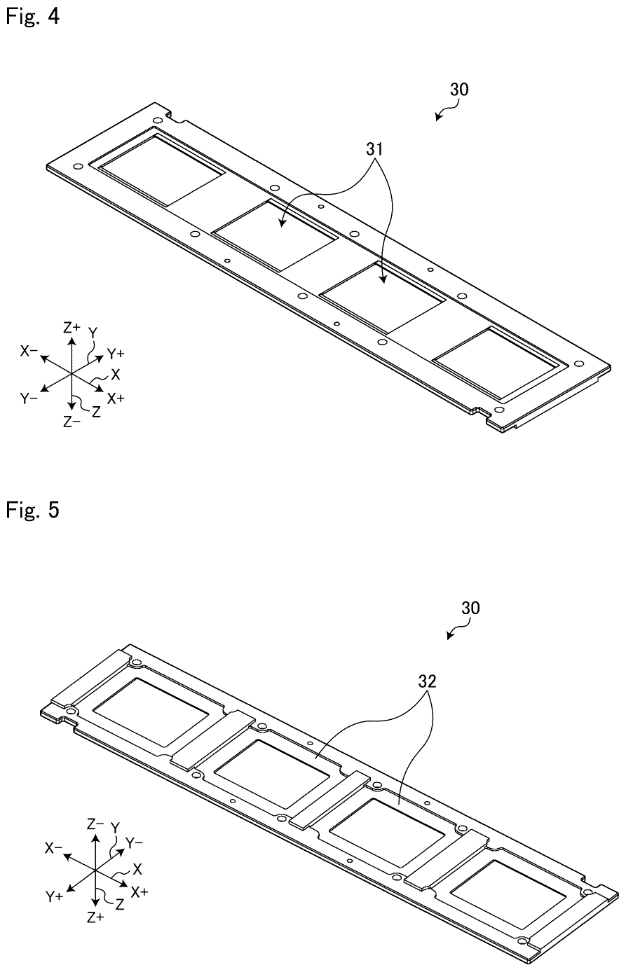

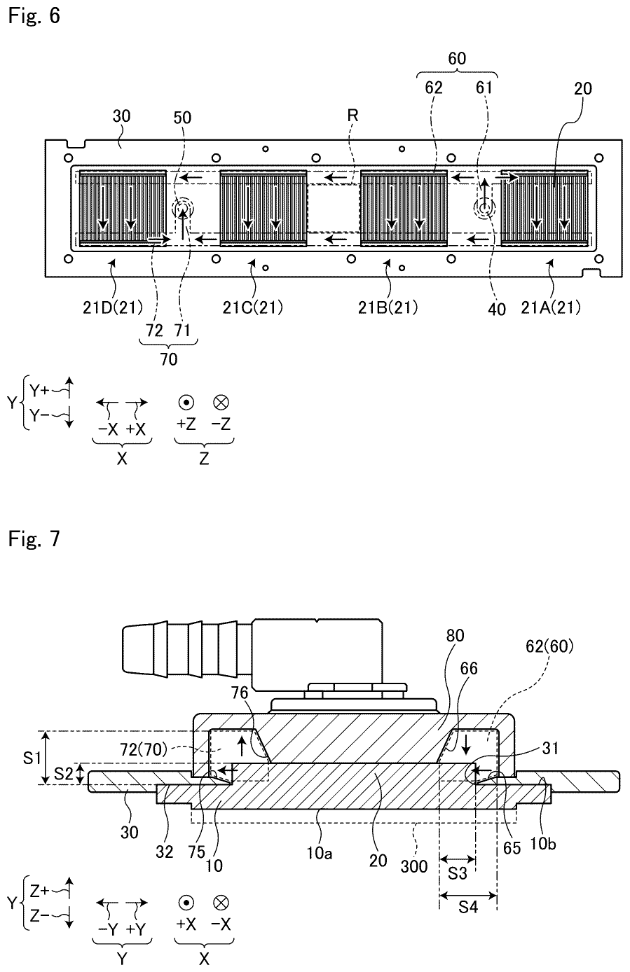

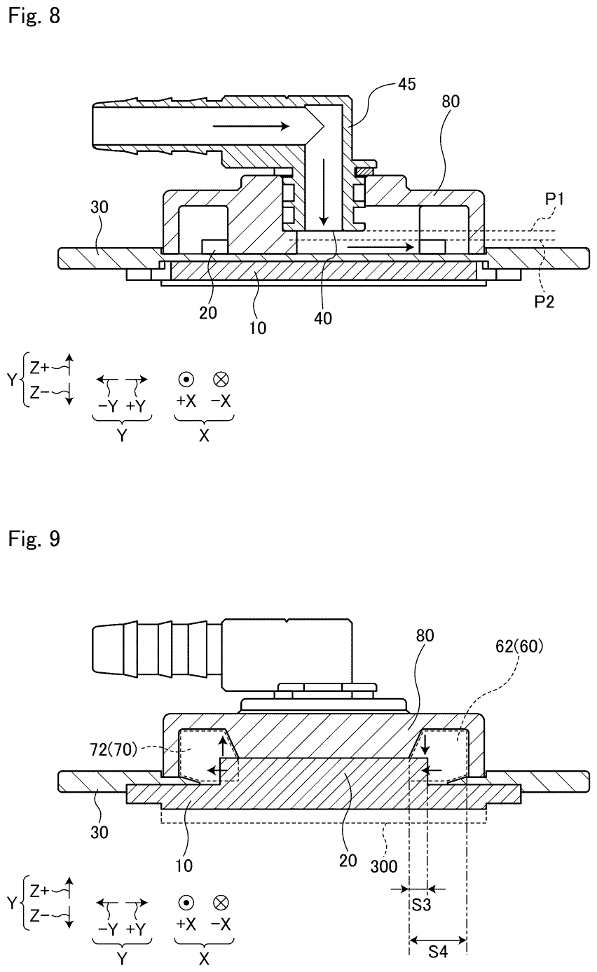

First, a configuration of a cooling device 100 according to a first example embodiment will be described with reference to FIGS. 1 to 8. FIGS. 1 and 2 are schematic perspective views of the cooling device 100 according to the first example embodiment. FIG. 3 is a schematic perspective view of a cold plate 10 according to the first example embodiment. FIGS. 4 and 5 are schematic perspective views of an intermediate plate 30 according to the first example embodiment. FIG. 6 is a schematic plan view of the cooling device 100 according to the first example embodiment. FIG. 7 is a cross-sectional view taken along line IV-IV shown in FIG. 1. FIG. 8 is a cross-sectional view taken along line V-V shown in FIG. 1. For easy understanding, a cover 80 is omitted in FIG. 6.

As illustrated in FIGS. 1 to 8, the cooling device 100 includes a plurality of cold plates 10, a plurality of fins 20, an intermediate plate 30, and the cover 80. In addition, the cooling device 100 includes an inlet 40, an outlet 50, a first flow path 60, and a second flow path 70.

The cold plates 10 come into thermal contact with a heat source 300 (see FIG. 7) to be cooled. The cold plates 10 may be in direct contact with the heat source 300 or may be in indirect contact with the heat source via a heat transfer member such as a heat transfer sheet. The cold plate 10 may be made of a material having excellent thermal conductivity such as metal.

As illustrated in FIG. 2, the cooling device 100 may include a plurality of cold plates 10. The plurality of cold plates 10 are arranged to be spaced apart from each other in the X axis direction. One heat source 300 may be in thermal contact with each cold plate 10. In the example of FIG. 2, the cooling device 100 includes four cold plates 10.

As illustrated in FIG. 7, the cold plate 10 has a first surface 10a to be in contact with the heat source 300 and a second surface 10b located opposite to the first surface 10a.

The plurality of fins 20 are disposed on the second surface 10b of the cold plate 10. The plurality of fins 20 are arranged at intervals in the X axis direction. Each of the fins 20 is a rectangular plate-like member extending in the Y axis direction, and is disposed so as to be orthogonal to the second surface 10b of the cold plate 10. The fin 20 may be made of a material having excellent thermal conductivity such as metal. The plurality of fins 20 may be integrally formed with the cold plate 10.

The plurality of fins 20 disposed on one cold plate 10 constitute a fin group 21. As illustrated in FIG. 6, the cooling device 100 includes a plurality of fin groups 21. The plurality of fin groups 21 are arranged at intervals in the X axis direction. The interval between two adjacent fin groups 21 may be larger than the interval between two adjacent fins 20. In the example of FIG. 6, the cooling device 100 includes four fin groups 21.

The intermediate plate 30 is a plate-shaped member extending in the X axis direction. A plurality of through holes 31 (see FIG. 4) are formed in the intermediate plate 30. The plurality of through holes 31 are arranged at intervals in the X axis direction. The fins 20 integrally formed with the cold plate 10 are fitted into the through holes 31. A plurality of grooves 32 are formed in the intermediate plate 30. Each groove 32 is located on the lower surface (main surface on the Z axis negative direction side) of the intermediate plate 30, and is provided corresponding to each of the plurality of through holes 31. The cold plate 10 is fitted into each of the grooves 32, and the cold plate 10 is positioned.

The cover 80 is a box-shaped member extending in the X axis direction, and is located on the second surface 10b side of the cold plate 10. The cover 80 is disposed so as to cover the plurality of fins 20. The cover 80 may be made of, for example, metal.

In the plan view of the cooling device 100, a region R (see FIG. 6) sandwiched between the adjacent fin groups 21 and between the first flow path 60 and the second flow path 70 is disposed such that the upper surface of the intermediate plate 30 and the lower surface of the cover 80 are in contact with each other.

The inlet 40 communicates with the first flow path 60 and serves as an inlet for the refrigerant into the cooling device 100. The outlet 50 communicates with the second flow path 70 and serves as an outlet for the refrigerant from the inside of the cooling device 100.

The inlet 40 and the outlet 50 are located in the cover 80. For example, the cover 80 has two openings penetrating in the Z axis direction. One end portions of tubular members 45 and 55 are inserted into the two openings, respectively. The other end portions of the tubular members 45 and 55 protrude toward the Z axis positive direction side from the cover 80. The cooling device 100 includes the through holes for the tubular members 45 and 55 as the inlet 40 and the outlet 50, respectively. As illustrated in FIG. 1, the tubular members 45 and 55 may be curved members.

The first flow path 60 communicates with the inlet 40. As illustrated in FIGS. 6 and 7, the first flow path 60 is disposed on one side (Y axis positive direction side) in the Y axis direction with respect to the plurality of fins 20 on the second surface 10b of the cold plate 10.

The first flow path 60 includes a first individual flow path 61 communicating with the inlet 40 and a second individual flow path 62 communicating with the first individual flow path 61. The first individual flow path 61 is a flow path extending in the Y axis positive direction from the inlet 40. The second individual flow path 62 is a flow path that is disposed on the Y axis positive direction side with respect to the plurality of fins 20 and extends in the X axis direction. The first individual flow path 61 and the second individual flow path 62 are constituted by grooves formed in the cover 80. The refrigerant flowing from the inlet 40 passes through the first individual flow path 61 and the second individual flow path 62, and flows between the two adjacent fins 20 from the Y axis positive direction side.

The second flow path 70 communicates with the outlet 50. As illustrated in FIGS. 6 and 7, the second flow path 70 is disposed on the other side (Y axis negative direction side) in the Y axis direction with respect to the plurality of fins 20 on the second surface 10b of the cold plate 10.

The second flow path 70 includes a third individual flow path 71 communicating with the outlet 50, and a fourth individual flow path 72 communicating with the third individual flow path 71. The third individual flow path 71 is a flow path extending from the outlet 50 in the Y axis negative direction. The fourth individual flow path 72 is a flow path that is disposed on the Y axis negative direction side with respect to the plurality of fins 20 and extends in the X axis direction. The third individual flow path 71 and the fourth individual flow path 72 are constituted by grooves formed in the cover 80. The refrigerant flowing between the two fins 20 adjacent to each other from the Y axis positive direction side to the Y axis negative direction side passes through the fourth individual flow path 72 and the third individual flow path 71, and flows out from the outlet 50.

As described above, in the cooling device 100 according to the first example embodiment, the refrigerant flows into the cooling device 100 from the inlet 40. Thereafter, the refrigerant flows between the two adjacent fins 20 via the first flow path 60. At this time, the refrigerant exchanges heat with the heat source 300 via the fins 20 and the cold plate 10. As a result, the heat source 300 is cooled. Then, the refrigerant passes between the two adjacent fins 20, flows to the second flow path 70, and flows out of the cooling device 100 from the outlet 50.

At least a portion of the fin 20 of the cooling device 100 according to the first example embodiment overlaps the first flow path 60 or the second flow path 70 in plan view. As illustrated in FIG. 6, one end portion of the fin 20 in the Y axis direction overlaps the first flow path 60 in plan view. Specifically, one end portion of the fin 20 in the Y axis direction overlaps the second individual flow path 62 of the first flow path 60 in plan view.

Similarly, the other end portion of the fin 20 in the Y axis direction overlaps the second flow path 70 in plan view. Specifically, the other end portion of the fin 20 in the Y axis direction overlaps the fourth individual flow path 72 of the second flow path 70 in plan view.

As described above, at least a portion of the fin 20 overlaps the first flow path 60 or the second flow path 70 in plan view, so that the refrigerant can pass not only from the lateral side of the fin 20 but also from the upper side. That is, the refrigerant flowing from the first flow path 60 into the space between the two adjacent fins 20 or the refrigerant flowing from the space between the two adjacent fins 20 to the second flow path 70 can be increased, so that the refrigerant flow efficiency can be improved. Therefore, the cooling device 100 is excellent in cooling efficiency.

The cold plate 10, the fins 20, and the inlet 40 may be arranged in the order of the cold plate 10, the fins 20, and the inlet 40 in the Z axis direction. Specifically, as illustrated in FIG. 8, the cold plate 10, the fins 20, and the inlet 40 may be arranged in the order of the cold plate 10, the fins 20, and the inlet 40 in the Z axis positive direction. That is, the refrigerant inlet 40 may be disposed above the fins 20 and the cold plate 10.

By arranging the cold plate 10, the fins 20, and the inlet 40 in this manner, the refrigerant easily flows from the top to the bottom, so that a large amount of refrigerant can be easily introduced between the two adjacent fins 20.

As illustrated in FIG. 8, a position P2 of the upper end of the fin 20 in the Z axis direction may be located closer to the cold plate 10 side than a position P1 of the lower end of the inlet 40 in the Z axis direction. That is, the position P2 of the upper end of the fin 20 may be located below the position P1 of the lower end of the inlet 40. According to such a configuration, since the inlet 40 is positioned above the fins 20, the refrigerant easily flows from the inlet 40 above the fins 20. In addition, due to the weight of the refrigerant, the refrigerant can be easily introduced between the two fins 20 adjacent to each other from above the fins 20.

As illustrated in FIG. 8, the inlet 40 and the outlet 50 may overlap the fins 20 in the X axis direction.

According to such a configuration, as compared with the case where the inlet 40 and the outlet 50 are located at positions sandwiching the fin group 21 in a direction in which the fin group 21 extends (here, in the Y axis direction) or the case where the inlet 40 and the outlet 50 are located on one side in the Y axis direction with respect to the fin group 21, the width in the direction in which the fins 20 extend can be reduced. Therefore, the cooling device 100 can be downsized.

The inlet 40 and the outlet 50 may be located between two adjacent fin groups 21. Specifically, as illustrated in FIG. 6, the inlet 40 may be located between two adjacent fin groups 21A and 21B. The outlet 50 may be located between two adjacent fin groups 21C and 21D.

According to such a configuration, the width in the direction in which the fin groups 21 are arranged can be reduced as compared with the case where the inlet 40 and the outlet 50 are located at positions sandwiching all (here, four) of the fin groups 21 in a direction in which the fin group 21 extends (here, in the X axis direction) or the case where the inlet 40 and the outlet 50 are located on one side in the X axis direction with respect to all of the fin groups 21. Therefore, the cooling device 100 can be downsized.

In addition, in the direction in which the fin groups 21 are arranged, one fin group 21 may be located on a side opposite to the outlet 50 across the inlet 40. In the example illustrated in FIG. 6, the fin group 21A is located on a side opposite to the outlet 50 across the inlet 40. That is, one fin group 21A is positioned on the X axis positive direction side with respect to inlet 40.

According to such a configuration, as compared with the case where the inlet 40 is located near the center in the direction in which the fin groups 21 are arranged, the refrigerant flowing between the fins 20 adjacent to each other in the fin group 21A easily flows to the outlet 50 side (from the X axis positive direction side to the X axis negative direction side) in the second flow path 70.

In addition, in the direction in which the fin groups 21 are arranged, one fin group 21 may be located on a side opposite to the inlet 40 across the outlet 50. In the example illustrated in FIG. 6, the fin group 21D is located on a side opposite to the inlet 40 across the outlet 50. That is, one fin group 21D is positioned on the X axis negative direction side with respect to the outlet 50.

According to such a configuration, as compared with the case where the outlet 50 is located near the center in the direction in which the fin groups 21 are arranged, the refrigerant flowing between the fins 20 adjacent to each other in the fin group 21D easily flows to the outlet 50 side (from the X axis negative direction side to the X axis positive direction side) in the second flow path 70.

As illustrated in FIG. 7, a dimension S1 of the first flow path 60 or the second flow path 70 in the Z axis direction may be twice or more a dimension S2 of the fin 20 in the Z axis direction.

According to such a configuration, by expanding the space above the fins 20, the flow path resistance is reduced, and the refrigerant easily flows above the fins 20. Therefore, more refrigerant can be introduced between the two adjacent fins 20 from above the fins 20.

The dimension S2 of the fin 20 in the Z axis direction may be smaller than a value obtained by subtracting the dimension S2 from the dimension S1 of the first flow path 60 or the second flow path 70 in the Z axis direction. As a result, by expanding the space above the fins 20, the flow path resistance decreases, and the refrigerant easily flows above the fins 20. Therefore, more refrigerant can be introduced between the two adjacent fins 20 from above the fins 20.

As illustrated in FIG. 7, in a cross-sectional view perpendicular to the X axis direction, a bottom surface 65 of the first flow path 60 may be inclined in a direction (here, in the Z axis negative direction) in which the bottom surface approaches the second surface 10b of the cold plate 10 as approaching the fins 20. According to such a configuration, the refrigerant flowing through the first flow path 60 is easily guided between the two adjacent fins 20.

Similarly, a bottom surface 75 of the second flow path 70 may be inclined in a direction in which the bottom surface approaches the second surface 10b of the cold plate 10 as approaching the fins 20. According to such a configuration, the refrigerant flowing between the two fins 20 adjacent to each other is easily guided to the second flow path 70 and the outlet 50.

As illustrated in FIG. 7, in a cross-sectional view perpendicular to the X axis direction, a side surface 66 of the first flow path 60 located above the fins 20 may be inclined in a direction approaching the central portions of the fins 20 in the Y axis direction as approaching the fins 20. According to such a configuration, by expanding the space above the fins 20, the flow path resistance is reduced, and the refrigerant easily flows above the fins 20. Therefore, more refrigerant can be introduced between the two adjacent fins 20 from above the fins 20.

Similarly, a side surface 76 of the second flow path 70 located above the fins 20 may be inclined in a direction approaching the central portions of the fins 20 in the Y axis direction as approaching the fins 20. According to such a configuration, by expanding the space above the fins 20, the flow path resistance is reduced, and the refrigerant easily flows above the fins 20. Therefore, the refrigerant flowing between the two fins 20 adjacent to each other is easily guided to the second flow path 70 and the outlet 50.

As illustrated in FIG. 7, a dimension in the Y axis direction of a portion of the fin 20 overlapping the first flow path 60 is defined as a first dimension S3, and a dimension in the Y axis direction of the first flow path 60 is defined as a second dimension S4. In this case, the first dimension S3 may be larger than a value obtained by subtracting the first dimension S3 from the second dimension S4.

According to such a configuration, since the dimension of the fin 20 in the Y axis direction is large, the fin 20 can be enlarged, and the cooling performance of the cooling device 100 can be improved.

As illustrated in FIG. 7, the dimension S3 in the Y axis direction of the portion of the fin 20 overlapping the first flow path 60 may be larger than the dimension S2 of the portion in the Z axis direction.

According to such a configuration, the refrigerant easily flows to the lateral side of the fin 20. Therefore, more refrigerant can be introduced between the two fins 20 adjacent to each other from the lateral side of the fin 20.

As described above, in the cooling device 100 according to the first example embodiment, at least a portion of the fin 20 overlaps the first flow path 60 or the second flow path 70 in plan view. This allows the refrigerant to pass not only from the lateral side of the fin 20 but also from the upper side. That is, the refrigerant flowing from the first flow path 60 into the space between the two adjacent fins 20 or the refrigerant flowing from the space between the two adjacent fins 20 to the second flow path 70 can be increased, so that the refrigerant flow efficiency can be improved. Therefore, the cooling device 100 is excellent in cooling efficiency.

FIG. 9 is a schematic cross-sectional view of a cooling device 100 according to a second example embodiment. As illustrated in FIG. 9, a dimension in the Y axis direction of a portion of the fin 20 overlapping the first flow path 60 is defined as a first dimension S3, and a dimension in the Y axis direction of the first flow path 60 is defined as a second dimension S4. In this case, the first dimension S3 may be smaller than a value obtained by subtracting the first dimension S3 from the second dimension S4.

According to such a configuration, since the amount of the refrigerant flowing from the lateral side of the fin 20 can be increased, the cooling performance of the cooling device 100 can be improved.

The present technique can be configured as follows.
(1) A cooling device including:
a cold plate in thermal contact with a heat source;
a plurality of fins arranged at intervals in a first direction on one main surface of two main surfaces of the cold plate;
a first flow path that is on one side of the plurality of fins on the one main surface in a second direction intersecting a first direction, and communicates with an inlet of a refrigerant; and
a second flow path that is on another side of the plurality of fins on the one main surface in the second direction, and communicates with an outlet of the refrigerant; in which
at least a portion of each of the plurality of fins overlaps the first flow path or the second flow path in a plan view.
(2) The cooling device according to (1), in which
one end portion of each of the plurality of fins in the second direction overlaps the first flow path in the plan view, and
another end portion of each of the plurality of fins in the second direction overlaps the second flow path in the plan view.
(3) The cooling device according to (1) or (2), in which when a direction intersecting the first direction and the second direction is defined as a third direction, the cold plate, the plurality of fins, and the inlet are arranged in the third direction in an order of the cold plate, the plurality of fins, and the inlet.
(4) The cooling device according to any one of (1) to (3), in which the inlet and the outlet overlap the plurality of fins in the first direction.
(5) The cooling device according to any one of (1) to (4), further including a plurality of fin groups in which the plurality of fins are arranged in the first direction, in which
the inlet and the outlet are located between two of the plurality of fin groups which are adjacent to each other.
(6) The cooling device according to any one of (1) to (5), in which when a direction intersecting the first direction and the second direction is a third direction, a dimension of the first flow path or the second flow path in the third direction is about two times or more a dimension of each of the plurality of fins in the third direction.
(7) The cooling device according to any one of (1) to (6), in which in a cross-sectional view perpendicular to the first direction, a bottom surface of the first flow path or a bottom surface of the second flow path is inclined in a direction approaching the one main surface as approaching the plurality of fins.
(8) The cooling device according to any one of (1) to (7), in which in a cross-sectional view perpendicular to the first direction, a side surface of the first flow path located above the plurality of fins or a side surface of the second flow path located above the plurality of fins is inclined in a direction approaching central portions of the plurality of fins in the second direction as approaching the plurality of fins.
(9) The cooling device according to any one of (1) to (8), in which when a dimension in the second direction of the portion of each of the plurality of fins overlapping the first flow path is defined as a first dimension and a dimension in the second direction of the first flow path is defined as a second dimension, the first dimension is larger than a value obtained by subtracting the first dimension from the second dimension.
(10) The cooling device according to any one of (1) to (8), in which when a dimension in the second direction of the portion of each of the plurality of fins overlapping the first flow path is defined as a first dimension and a dimension in the second direction of the first flow path is defined as a second dimension, the first dimension is smaller than a value obtained by subtracting the first dimension from the second dimension.
(11) The cooling device according to any one of (1) to (9), in which when a direction intersecting the first direction and the second direction is defined as a third direction, a dimension in the second direction of the portion of each of the plurality of fins overlapping the first flow path is larger than a dimension in the third direction of the portion.

It should be understood that the example embodiments disclosed herein are illustrative in all respects and not restrictive. In fact, the above example embodiments can be implemented in a variety of forms. Various forms of elimination, replacement, and modification may be applied to the above example embodiments without departing from the spirit and the scope of claims appended.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a cold plate configured to be in thermal contact with a heat source;
a plurality of fins arranged at intervals in a first direction on one main surface of two main surfaces of the cold plate;
a first flow path that is on one side of the plurality of fins on the one main surface in a second direction intersecting a first direction, and communicates with an inlet of a refrigerant; and
a second flow path that is on another side of the plurality of fins on the one main surface in the second direction, and communicates with an outlet of the refrigerant; wherein
at least a portion of each of the plurality of fins overlaps the first flow path or the second flow path in a plan view.

2. The cooling device according to claim 1, wherein
one end portion of each of the plurality of fins in the second direction overlaps the first flow path in the plan view; and
another end portion of each of the plurality of fins in the second direction overlaps the second flow path in the plan view.

3. The cooling device according to claim 1, wherein when a direction intersecting the first direction and the second direction is defined as a third direction, the cold plate, the plurality of fins, and the inlet are arranged in the third direction in an order of the cold plate, the plurality of fins, and the inlet.

4. The cooling device according to claim 1, wherein the inlet and the outlet overlap the plurality of fins in the first direction.

5. The cooling device according to claim 1, further comprising a plurality of fin groups in which the plurality of fins are arranged in the first direction, wherein the inlet and the outlet are located between two of the plurality of fin groups which are adjacent to each other.

6. The cooling device according to claim 1, wherein when a direction intersecting the first direction and the second direction is defined as a third direction, a dimension of the first flow path or the second flow path in the third direction is about two times or more a dimension of each of the plurality of fins in the third direction.

7. The cooling device according to claim 1, wherein in a cross-sectional view perpendicular to the first direction, a bottom surface of the first flow path or a bottom surface of the second flow path is inclined in a direction approaching the one main surface as approaching the plurality of fins.

8. The cooling device according to claim 1, wherein in a cross-sectional view perpendicular to the first direction, a side surface of the first flow path located above the plurality of fins or a side surface of the second flow path located above the plurality of fins is inclined in a direction approaching central portions of the plurality of fins in the second direction as approaching the plurality of fins.

9. The cooling device according to claim 1, wherein when a dimension in the second direction of the portion of each of the plurality of fins overlapping the first flow path is defined as a first dimension and a dimension in the second direction of the first flow path is defined as a second dimension, the first dimension is larger than a value obtained by subtracting the first dimension from the second dimension.

10. The cooling device according to claim 1, wherein when a dimension in the second direction of the portion of each of the plurality of fins overlapping the first flow path is defined as a first dimension and a dimension in the second direction of the first flow path is defined as a second dimension, the first dimension is smaller than a value obtained by subtracting the first dimension from the second dimension.

11. The cooling device according to claim 1, wherein when a direction intersecting the first direction and the second direction is defined as a third direction, a dimension in the second direction of the portion of each of the plurality of fins overlapping the first flow path is larger than a dimension in the third direction of the portion.
